(19) United States
(12) Patent Application Publication
(10) Pub. No.: US 2022/0336533 A1
(43) Pub. Date: Oct. 20, 2022

(54) SEMICONDUCTOR DEVICE INCLUDING RESISTANCE CHANGE LAYER WITH CARBON NANOSTRUCTURES

(71) Applicant: SK hynix Inc., Icheon-si (KR)

(72) Inventor: Jae Gil LEE, Icheon-si (KR)

(73) Assignee: SK hynix Inc.

(21) Appl. No.: 17/491,916

(22) Filed: Oct. 1, 2021

(30) Foreign Application Priority Data
Apr. 20, 2021 (KR) 10-2021-0051421

(51) Int. Cl. H01L 27/28; H01L 51/00; H01L 51/05

(52) U.S. Cl. CPC H01L 27/285; H01L 27/281; H01L 51/0048; H01L 51/0591

(57) ABSTRACT

A semiconductor device according to an embodiment of the present disclosure includes a substrate, a resistance change layer disposed on the substrate and including a plurality of carbon nanostructures, a channel layer disposed on the resistance change layer, a gate electrode layer disposed on the channel layer, and a source electrode layer and a drain electrode layer disposed to contact portions of the channel layer.

### CROSS-REFERENCE TO RELATED APPLICATIONS

The present application claims priority under 35 U.S.C. § 119(a) to Korean Application No. 10-2021-0051421, filed on Apr. 20, 2021 in the Korean Intellectual Property Office, which is incorporated herein by reference in its entirety.

### BACKGROUND

### 1. Technical Field

The present disclosure generally relates to a semiconductor device including a resistance change layer.

### 2. Related Art

Research on semiconductor memory devices capable of ensuring structural stability and reliability of signal storage operations continues in view of trends in decreasing design rules and in increasing of the degree of integration. Currently, a semiconductor memory device such as a flash memory is widely used as a charge storage structure because of its three-layer stack structure including a charge tunneling layer, a charge trap layer, and a charge barrier layer.

Recently, various semiconductor memory devices having structures that are different from flash memory structures have been proposed. A resistance change memory device is an example of the semiconductor memory device with a different structure. Whereas a flash memory implements a memory function through charge storage, a resistance change memory device may implement a memory function by variably changing a resistance state of a memory layer, located in a memory cell, between a high resistance state and a low resistance state, and then storing the changed resistance state in a non-volatile manner. Currently, in order to improve the performance of the memory function in such devices, various studies on the material and structure of the memory layer are being conducted.

### SUMMARY

A semiconductor device according to an embodiment of the present disclosure includes a substrate, a resistance change layer disposed on the substrate and including a plurality of carbon nanostructures, a channel layer disposed on the resistance change layer, a gate electrode layer disposed on the channel layer, and a source electrode layer and a drain electrode layer disposed to contact portions of the channel layer.

A semiconductor device according to another embodiment of the present disclosure includes a conductive gate substrate, a gate dielectric layer disposed on the conductive gate substrate, a channel layer disposed on the gate dielectric layer and including a semiconductor material, a source electrode layer and a drain electrode layer disposed on the gate dielectric layer to contact opposite ends of the channel layer, and a resistance change layer disposed over the conductive gate substrate to contact the source electrode layer, the drain electrode layer, and the channel layer. The resistance change layer includes a plurality of carbon nanostructures.

A semiconductor device according to yet another embodiment of the present disclosure includes a substrate, a gate structure disposed over the substrate, a channel layer including a semiconductor material that is disposed on the substrate and along a sidewall surface of the gate structure, and a resistance change layer disposed over the substrate to contact the channel layer and including a plurality of carbon nanostructures. The gate structure includes at least one gate electrode layer and at least one interlayer insulating layer that are alternately stacked.

### BRIEF DESCRIPTION OF THE DRAWINGS

FIG. 1A is a cross-sectional view schematically illustrating a semiconductor device according to an embodiment of the present disclosure.

FIG. 1B is a schematic circuit diagram of the semiconductor device of FIG. 1A.

FIGS. 2A and 2B are views schematically illustrating a distribution state of carbon nanostructures in a resistance change layer according to an embodiment of the present disclosure.

FIGS. 3A and 3B are cross-sectional views schematically illustrating a method of operating a semiconductor device according to an embodiment of the present disclosure.

FIG. 4 is a graph schematically illustrating a method of reading signal information stored in a semiconductor device according to an embodiment of the present disclosure.

FIG. 5 is a cross-sectional view schematically illustrating a semiconductor device according to another embodiment of the present disclosure.

FIG. 6 is a cross-sectional view schematically illustrating a semiconductor device according to yet another embodiment of the present disclosure.

FIG. 7 is a perspective view schematically illustrating a semiconductor device according to yet another embodiment of the present disclosure.

FIG. 8 is a cross-sectional view taken along line I-I′ of the semiconductor device of FIG. 7.

FIG. 9 is a circuit diagram of a semiconductor device according to an embodiment of the present disclosure.

FIGS. 10 to 12 are diagrams schematically illustrating an operation of a semiconductor device according to an embodiment of the present disclosure.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

Further, in performing a method or a manufacturing method, each process constituting the method can take place differently from the stipulated order unless a specific sequence is described explicitly in the context. In other words, each process may be performed in the same manner as stated order, and may be performed substantially at the same time. Also, at least a part of each of the above processes may be performed in a reversed order.

In this specification, the term “a predetermined direction” may mean a direction encompassing one direction determined in a coordinate system and a direction opposite to that direction. As an example, in the x-y-z coordinate system, the x-direction may encompass a direction parallel to the x-direction. That is, the x-direction may mean all of a direction in which an absolute value of the x-axis increases in a positive direction along the x-axis from the origin 0 and a direction in which an absolute value of the x-axis increases in a negative direction along the x-axis from the origin 0. The y-direction and the z-direction may each be interpreted in substantially the same way in the x-y-z coordinate system.

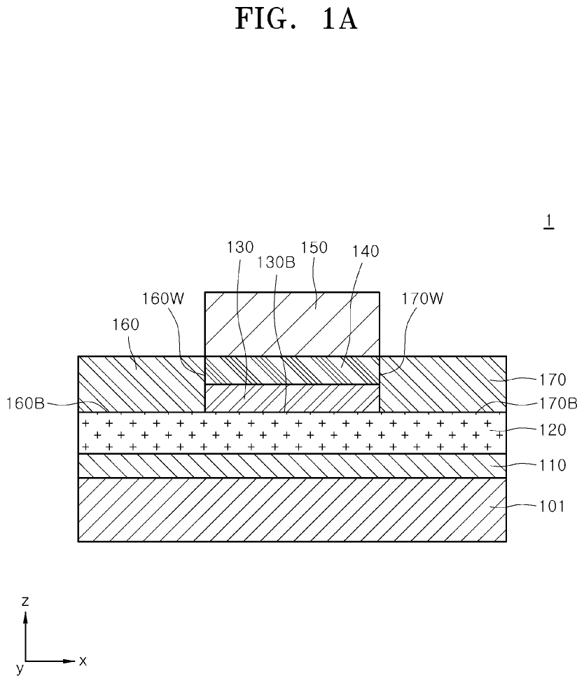

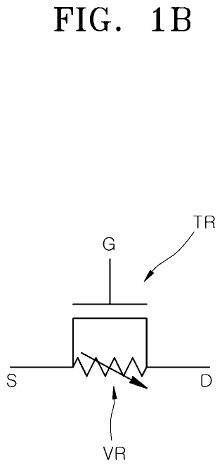

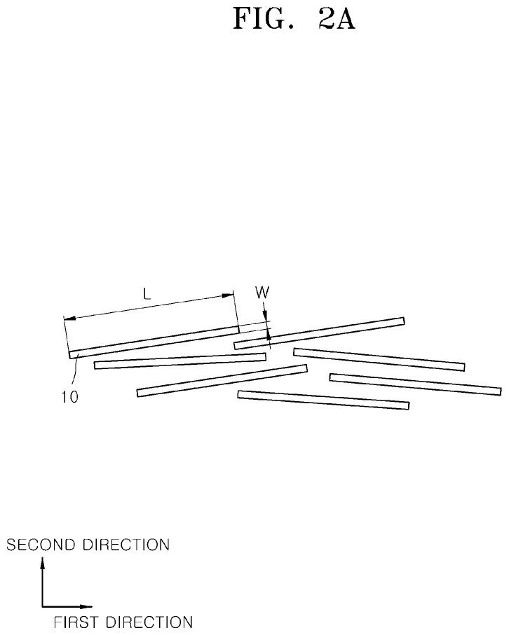

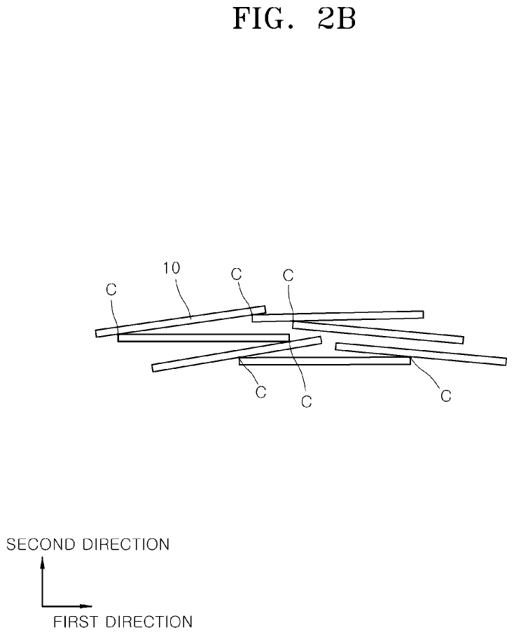

FIG. 1A is a cross-sectional view schematically illustrating a semiconductor device according to an embodiment of the present disclosure. In an embodiment, the semiconductor device of FIG. 1A may be a nonvolatile memory device. FIG. 1B is a schematic circuit diagram of the semiconductor device of FIG. 1A. FIGS. 2A and 2B are views schematically illustrating a distribution state of carbon nanostructures in a resistance change layer according to an embodiment of the present disclosure.

Referring to FIG. 1A, a semiconductor device 1 may include a substrate 101, a resistance change layer 120 disposed over the substrate 101, a channel layer 130 disposed on the resistance change layer 120, a gate electrode layer 150 disposed over the channel layer 130, and a source electrode layer 160 and a drain electrode layer 170 respectively disposed to contact different portions of the channel layer 130. The source electrode layer 160 and the drain electrode layer 170 may be respectively disposed to contact opposite ends of the channel layer 130. In addition, the semiconductor device 1 may further include a gate dielectric layer 140 disposed between the channel layer 130 and the gate electrode layer 150. The semiconductor device 1 may further include a base insulating layer 110 disposed between the substrate 101 and the resistance change layer 120.

Referring to FIG. 1B, the semiconductor device 1 of FIG. 1A may include a field effect transistor TR including a gate electrode G, a source electrode S, and a drain electrode D, and a variable resistance element VR disposed in a channel region of the field effect transistor TR. The gate electrode G, the source electrode S, the drain electrode D, and the variable resistance element VR of FIG. 1B may correspond to the gate electrode layer 150, the source electrode layer 160, the drain electrode layer 170, and the resistance change layer 120 of FIG. 1A, respectively.

Referring to FIG. 1A again, the substrate 101 may include a semiconductor material. Specifically, the semiconductor material may include silicon (Si), germanium (Ge), gallium arsenide (GaAs), molybdenum selenide (MoSe₂), hafnium selenide (HfSe₂), indium selenide (InSe), gallium selenide (GaSe), black phosphorus, indium-gallium-zinc oxide (IGZO), or a combination of two or more thereof.

The base insulating layer 110 may be disposed on the substrate 101. The base insulating layer 110 may include, as an example, oxide, nitride, oxynitride, or two or more thereof. Although not illustrated in FIG. 1A, the substrate 101 may include an integrated circuit. As an example, the integrated circuit may constitute an active device such as a diode or a transistor. At least one conductive layer and at least one insulating layer may be disposed between the substrate 101 and the base insulating layer 110. The conductive layer and the insulating layer may constitute a passive element such as a capacitor or a resistor.

The resistance change layer 120 may be disposed on the base insulating layer 110. The resistance change layer 120 may include a plurality of carbon nanostructures. In an embodiment, the resistance change layer 120 may be an integrated body of the plurality of carbon nanostructures. The plurality of carbon nanostructures may have electrical conductivity. The plurality of carbon nanostructures may include, as an example, carbon nanotubes or carbon nanorods.

FIGS. 2A and 2B are views illustrating distribution states of a plurality of carbon nanostructures 10. Referring to FIGS. 2A and 2B, each of the plurality of carbon nanostructures 10 may have a width W and a length L. The width W and the length L may each have a size of 1 to 100 nm, as an example. The length L may be larger than the width W.

The plurality of carbon nanostructures 10 may have different distribution states in the resistance change layer 120. Referring to FIGS. 2A and 2B together, the plurality of carbon nanostructures 10 illustrated in FIG. 2A may have a relatively random distribution state relative to the plurality of carbon nanostructures 10 illustrated in FIG. 2B. The degree of alignment of the plurality of carbon nanostructures 10 of FIG. 2A in one direction may be relatively low. In addition, the frequency at which the plurality of carbon nanostructures 10 of FIG. 2A are bonded to each other may be relatively low. On the other hand, the plurality of carbon nanostructures 10 illustrated in FIG. 2B may be bonded to each other at a relatively higher frequency and have contact points C. The plurality of carbon nanostructures 10 may be generally aligned in a direction (e.g., a first direction) while being bonded to each other. That is, the plurality of carbon nanostructures 10 of FIG. 2B may be relatively more aligned in a first direction than the plurality of carbon nanostructures 10 of FIG. 2A.

According to an embodiment of the present disclosure, the distribution states of the plurality of carbon nanostructures 10 may be controlled through application of a voltage or an electric field. That is, through the application of voltage or electric field, bonding or separation between the plurality of carbon nanostructures 10 may occur. Meanwhile, even if the voltage or electric field is removed after the bonding or the separation between the plurality of carbon nanostructures 10 occurs, the distribution states of the plurality of carbon nanostructures 10 changed by the bonding or separation may be maintained. When the plurality of carbon nanostructures 10 are bonded to each other, after the voltage or electric field is removed, a van der Waals force may act between the plurality of carbon nanostructures 10 so that bonding between the plurality of carbon nanostructures 10 may be maintained.

According to an embodiment, as the plurality of carbon nanostructures 10 form more bonds, the distribution of the plurality of carbon nanostructures 10 may increase the electrical conductivity of the resistance change layer 120. As described later, the distribution and alignment of the plurality of carbon nanostructures 10 may be controlled through a voltage or an electric field applied between the source electrode layer 160 and the drain electrode layer 170. As an example, by increasing the magnitude of the voltage or electric field applied between the source electrode layer 160 and the drain electrode layer 170, the number of contact points C between the plurality of carbon nanostructures 10 may be increased, and the degree of alignment of the plurality of carbon nanostructures 10 along the x-direction may be improved. As a result, the electrical conductivity of the resistance change layer 120 between the source electrode layer 160 and the drain electrode layer 170 may be increased and the electrical resistance of the resistance change layer 120 may be decreased.

Referring to FIG. 1A, the channel layer 130 may be disposed on the resistance change layer 120. In an embodiment, the channel layer 130 may be disposed to contact the resistance change layer 120. The channel layer 130 may include a semiconductor material. The semiconductor material may include, as an example, silicon (Si), germanium (Ge), gallium arsenide (GaAs), or the like. As another example, the semiconductor material may include a two-dimensional (2D) semiconductor material. The 2D semiconductor material may include transition metal dichalcogenide (TMDC), black phosphorus, or the like. The transition metal dichalcogenide (TMDC) may include, as an example, molybdenum selenide (MoSe₂), hafnium selenide (HfSe₂), indium selenide (InSe), gallium selenide (GaSe), or the like. The semiconductor material may include, as an example, metal oxide such as indium-gallium-zinc oxide (IGZO).

The channel layer 130 may have conductivity. The conductivity may be generated by a dopant distributed in the semiconductor material. In an example, the conductivity of the channel layer 130 may be proportional to the amount of the dopant. The electrical resistance of the channel layer 130 may be higher than that of the resistance change layer 120. However, when a gate voltage greater than or equal to a threshold voltage is applied to the gate electrode layer 150 to form a conductive channel in the channel layer 130, the conductive channel may reduce the electrical resistance of the resistance change layer 120. The electrical resistance of the conductive channel may be lower than that of the resistance change layer 120.

Referring to FIG. 1A, the gate dielectric layer 140 may be disposed on the channel layer 130. The gate electrode layer 150 may be disposed on the gate dielectric layer 140. The gate dielectric layer 140 may include, as an example, oxide, nitride, oxynitride, or a combination of two or more thereof. Specifically, the gate dielectric layer 140 may include silicon oxide, silicon nitride, silicon oxynitride, aluminum oxide, hafnium oxide, zirconium oxide, or a combination of two or more thereof. The gate electrode layer 150 may include a conductive material. The conductive material may include, as an example, doped semiconductor, metal, conductive metal nitride, conductive metal carbide, conductive metal silicide, or conductive metal oxide. The conductive material may include, as an example, n-type doped silicon (Si), tungsten (T), titanium (Ti), copper (Cu), aluminum (Al), ruthenium (Ru), platinum (Pt), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

Referring to FIG. 1A, the source electrode layer 160 and the drain electrode layer 170 may be disposed to be spaced apart from each other on the resistance change layer 120. The source electrode layer 160 and the drain electrode layer 170 may be disposed to contact opposite ends of the channel layer 130, respectively. As illustrated in FIG. 1A, a side surface 160W of the source electrode layer 160 may be in contact with the channel layer 130 and the gate dielectric layer 140, and a lower surface 160B of the source electrode layer 160 may be in contact with the resistance change layer 120. The source electrode layer 160 and the drain electrode layer 170 may be electrically insulated from the gate electrode layer 150. Likewise, a side surface 170W of the drain electrode layer 170 may be in contact with the channel layer 130 and the gate dielectric layer 140, and a lower surface 170B of the drain electrode layer 170 may be in contact with the resistance change layer 120. In addition, the lower surface 160B of the source electrode layer 160, a lower surface 130B of the channel layer 130, and the lower surface 170B of the drain electrode layer 170 may be positioned at the same level, that is, on the same plane.

As described above, the semiconductor device 1 according to an embodiment of the present disclosure may include the resistance change layer disposed on the substrate, the channel layer disposed on the resistance change layer, the gate electrode layer disposed on the channel layer, and the source electrode layer and the drain electrode layer respectively contacting different portions of the channel layer. The resistance change layer may include a plurality of carbon nanostructures whose distribution state may be reversibly controlled. When the distribution state of the plurality of carbon nanostructures changes through increases or decreases in bonding and alignment, the electrical resistance of the resistance change layer may change. According to an embodiment of the present disclosure, by controlling the distribution state of the plurality of carbon nanostructures, the state of electrical resistance of the resistance change layer positioned between the source electrode layer and the drain electrode layer may be controlled. The semiconductor device 1 may be a nonvolatile memory device using the controlled electrical resistance state as signal information.

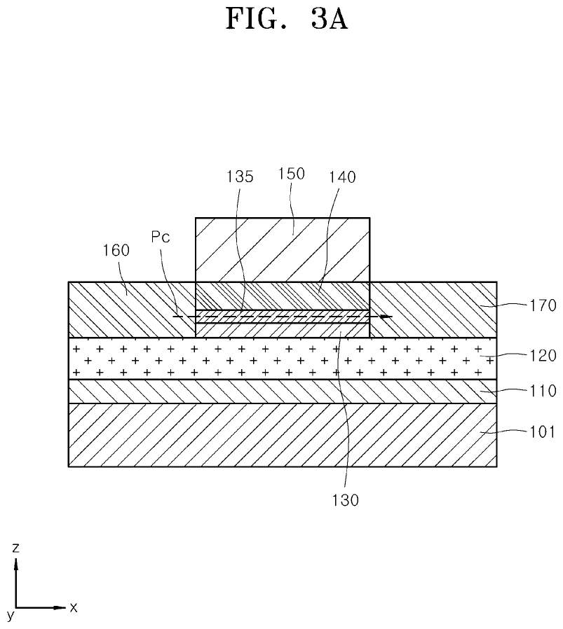

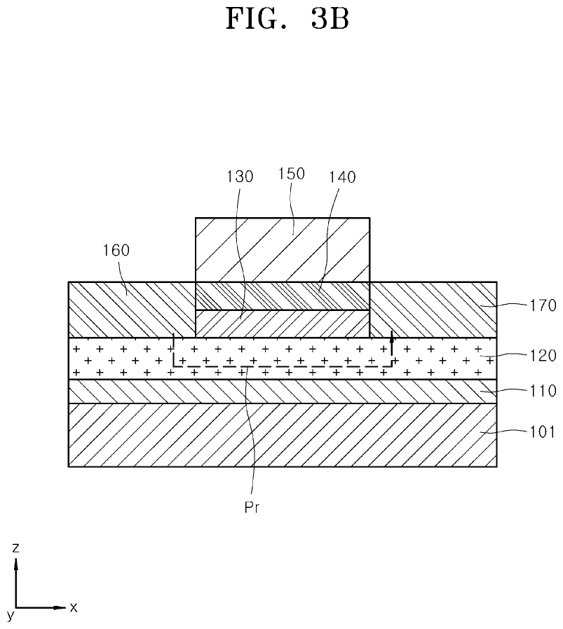

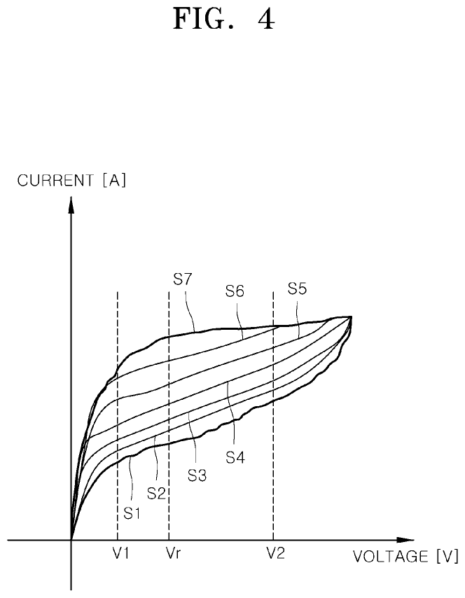

FIGS. 3A and 3B are cross-sectional views schematically illustrating a method of operating a semiconductor device according to an embodiment of the present disclosure. FIG. 4 is a graph schematically illustrating a method of reading signal information stored in a semiconductor device according to an embodiment of the present disclosure. The method of operating the semiconductor device described with reference to FIGS. 3A and 3B, and the method of reading signal information of the semiconductor device described with reference to FIG. 4, may be applied to the method of operating a semiconductor device 1 of FIG. 1A.

When a source-drain voltage is applied between a source electrode layer 160 and a drain electrode layer 170 of a semiconductor device 1 according to an embodiment of the present disclosure, a main conductive path of a conductive carrier may be divided into a first movement path Pc through a conductive channel 135 as illustrated in FIG. 3A, and a second movement path Pr through a resistance change layer 120 as illustrated in FIG. 3B. In this case, the conductive carrier may be an electron or a hole, as examples.

First, referring to FIG. 3A, the conduction of the conductive carrier through the first movement path Pc may be described as follows. The conductive channel 135 is formed in the channel layer 130 by applying a first gate voltage having a magnitude greater than or equal to a threshold voltage to a gate electrode layer 150 while the channel layer 130 is grounded. In addition, while the conductive channel 135 is formed, a source-drain voltage is applied between the source electrode layer 160 and the drain electrode layer 170. Because the electrical resistance of the conductive channel 135 is smaller than the electrical resistance of the resistance change layer 120, most of the conductive carriers may move from the source electrode layer 160 to the drain electrode layer 170 through the conductive channel 135. In an embodiment, when the source electrode layer 160 is grounded and a voltage having a positive polarity is applied to the drain electrode layer 170 in a state in which the conductive channel 135 is formed, electrons may move from the source electrode layer 160 to the drain electrode layer 170 through the conductive channel 135.

Referring to FIG. 3B, the conduction of the conductive carrier through the second movement path Pr may be described as follows. By applying a voltage of 0 V or by applying a second gate voltage having a magnitude smaller than a threshold voltage to the gate electrode layer 150, the state in which the conductive channel 135 of FIG. 3A is not formed in the channel layer 130 is maintained. In addition, in the state in which the conductive channel is not formed, a source-drain voltage is applied between the source electrode layer 160 and the drain electrode layer 170. In this case, because the electrical resistance of the resistance change layer 120 is smaller than that of the channel layer 130 in which the conductive channel is not formed, most of the conductive carriers may move from the source electrode layer 160 to the drain electrode layer 170 through the resistance change layer 120. In an embodiment, when the source electrode layer 160 is grounded and a voltage having a positive polarity is applied to the drain electrode layer 170, in a state in which the conductive channel is not formed, most of the electrons may be moved from the source electrode layer 160 to the drain electrode layer 170 through the resistance change layer 120.

A write operation of the semiconductor device 1, as illustrated in FIG. 3B, may be performed by reversibly changing the electrical resistance inside the resistance change layer 120 while moving the conductive carrier through the second movement path Pr. The resistance change layer 120 may include a plurality of carbon nanostructures. The write operation of the semiconductor device 1 may include a first write operation to reduce the electrical resistance of the resistance change layer 120 and a second write operation to increase the electrical resistance of the resistance change layer 120.

The first write operation of the semiconductor device 1 may proceed as follows. In an embodiment, in an initial state before the first write operation proceeds, the plurality of carbon nanostructures inside the resistance change layer 120 may have a random distribution state, as described with reference to FIG. 2A. The first write operation may be performed by grounding the source electrode layer 160 and applying a first drain voltage having a positive polarity to the drain electrode layer 170 in a state in which a conductive channel is not formed in the channel layer 130. When the first write operation is performed, an electrostatic attraction force acts between the plurality of carbon nanostructures in the resistance change layer 120 so that carbon nanostructures may be bonded to each other. In addition, carbon nanostructures bonded to each other by the electrostatic attraction force may be aligned in one direction (e.g., the x-direction). Even after the first drain voltage is removed, the bonding state and degree of alignment in the plurality of carbon nanostructures may be maintained. As described above in connection with FIG. 2B, the distribution state of the carbon nanostructures is changed to a state in which the plurality of carbon nanostructures are bonded and aligned with each other, so that the electrical resistance of the resistance change layer 120 may be decreased.

In an embodiment, as the magnitude of the first drain voltage increases, the number of contact points or bonds between the carbon nanostructures may increase. Alignment of the carbon nanostructures may also increase. As the number of the contact points between the carbon nanostructures increases, the electrical conductivity of the resistance change layer 120 between the source electrode layer 160 and the drain electrode layer 170 may be increased.

Using the above described characteristics, a plurality of different electrical resistance states may be implemented in the resistance change layer 120 during the first write operation. That is, in proportion to the magnitude of the voltage applied to the resistance change layer 120 (that is, the voltage between the source electrode layer 160 and the drain electrode layer 170), a characteristic in which the number of contact points between the plurality of carbon nanostructures increases may be used. By applying write voltages having different magnitudes to the resistance change layer 120 to differentiate bonding states of the plurality of carbon nanostructures, a plurality of electrical resistance states may be written in the resistance change layer 120. In an example, the bonding states may be determined by total numbers of bonding between the plurality of carbon nanostructures, or degrees of the alignment of the plurality of carbon nanostructures. The first write operation described above may be referred to as a “set operation” of the semiconductor device.

A second write operation of the semiconductor device 1 may proceed as follows. The second write operation may be an operation of reducing the number of contact points or bonding between the plurality of carbon nanostructures in the resistance change layer 120. In an embodiment, the second write operation may be an operation of restoring the bonding state of the plurality of carbon nanostructures acquired through the first write operation to an initial state of the random distribution state.

In an embodiment, the second write operation may be performed by grounding the source electrode layer 160 and applying a second drain voltage having a negative polarity to the drain electrode layer 170, in a state in which the conductive channel is not formed in the channel layer 130. The second drain voltage may have a polarity opposite to that of the first drain voltage. When the second write operation is performed, an electrostatic repulsive force may act between carbon nanostructures of the resistance change layer 120. The electrostatic repulsive force may desorb or repel the bonded carbon nanostructures from each other. Additionally, when the second write operation is performed, heat may be generated by phonon-vibration in the plurality of bonded carbon nanostructures. The generated heat may help the plurality of bonded carbon nanostructures to be desorbed and move away from each other.

In another embodiment, the second write operation may be performed by grounding the source electrode layer 160 and applying a third drain voltage having a positive polarity to the drain electrode layer 170, in a state in which the conductive channel is not formed in the channel layer 130. The third drain voltage may have the same polarity as the first drain voltage, but a level of the third drain voltage may be greater than that of the first drain voltage. When the third drain voltage is applied to the drain electrode layer 170, heat may be generated by phono-excitation in the plurality of carbon nanostructures. The heat may desorb the plurality of bonded carbon nanostructures from each other. In the above described embodiments, the second write operation may be referred to as a “reset operation” of the semiconductor device.

As described above, the first and second write operations of the semiconductor device 1 may be performed by controlling bonding and separation between the plurality of carbon nanostructures. The above described methods may be differentiated from the operation methods of controlling electrical resistance through a conductive filament formed in a variable resistance layer in a conventional resistance change memory device. Such a conventional operating method of the resistance change memory device may include a forming step of generating the conductive filament, a reset step of disconnecting the conductive filament, and a set step of connecting the disconnected conductive filament. In the forming step, a larger operating voltage may be applied to the variable resistance layer than in the reset step and the set step. In the writing method of the semiconductor device 1 according to an embodiment of the present disclosure, the forming step may be omitted from the operating method of the conventional resistance change memory device. That is, the writing method of the semiconductor device 1 does not require a forming step and may include a set operation and a reset operation that respectively correspond to the set step and the reset step of the operating method of the conventional resistance change memory device.

Meanwhile, as illustrated in FIG. 3B, a read operation of the semiconductor device 1 may proceed as a process of reading the electrical resistance inside the resistance change layer 120 in which the conductive carrier moves through the second movement path Pr.

In an embodiment, the read operation may be performed by grounding the source electrode layer 160 and applying a fourth drain voltage having a positive polarity to the drain electrode layer 170, in a state in which a conductive channel is not formed in the channel layer 130, to read a current flowing between the source electrode layer 160 and the drain electrode layer 170. Subsequently, the resistance state of the resistance change layer 120 may be determined through the read current.

During the period in which the fourth drain voltage is applied and the read operation is in progress, the bonding state of the plurality of carbon nanostructures in the resistance change layer 120 might not change. That is, during the fourth drain voltage is applied, the organization of the plurality of carbon nanostructures might not be altered by the application of the fourth drain voltage.

FIG. 4 is a graph illustrating a method of reading signal information stored in a semiconductor device according to an embodiment of the present disclosure. In FIG. 4, different first to seventh resistance states may be stored in the resistance change layer 120 of a semiconductor device 1 of FIGS. 3A and 3B according to an embodiment of the present disclosure. In an embodiment, the first write operation may utilize drain voltages of different magnitudes such that any of the first to seventh resistance states S1, S2, S3, S4, S5, S6, and S7 may be written in the resistance change layer 120.

The read voltage Vr for the read operation may be selected from a voltage range between the first voltage V1 and the second voltage V2 as illustrated in FIG. 4. The first voltage V1 may correspond to a lower limit at which the first to seventh resistance states S1, S2, S3, S4, S5, S6, and S7 may be distinguished from each other. The second voltage V2 may correspond to an upper limit at which the first to seventh resistance states S1, S2, S3, S4, S5, S6, and S7 may be distinguished from each other.

Subsequently, in a state in which a conductive channel is not formed in the channel layer 130, while applying the selected read voltage Vr between the source electrode layer 160 and the drain electrode layer 170, a current flowing between the source electrode layer 160 and the drain electrode layer 170 may be measured. The resistance state of the resistance change layer 120 may be determined as one of the first to seventh resistance states S1, S2, S3, S4, S5, S6, and S7 through the measured current.

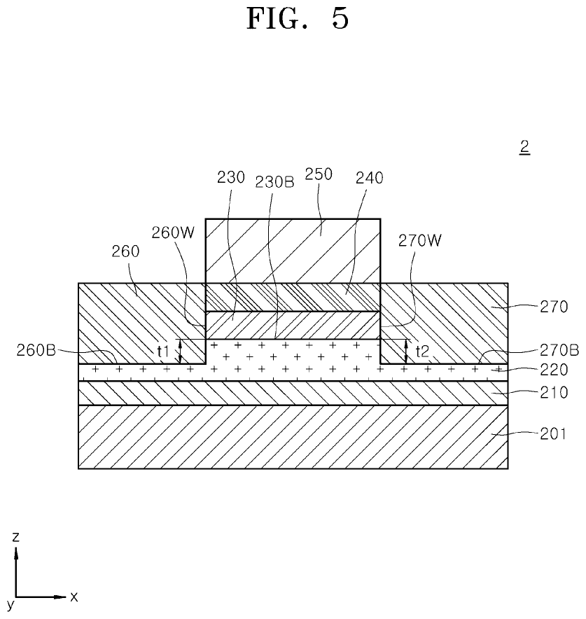

FIG. 5 is a cross-sectional view schematically illustrating a semiconductor device according to another embodiment of the present disclosure. Referring to FIG. 5, compared to the semiconductor device 1 of FIG. 1A, a semiconductor device 2 differs in the configurations of a resistance change layer 220, a source electrode layer 260, and a drain electrode layer 270.

The semiconductor device 2 may include a substrate 201, a base insulating layer 210 disposed on the substrate 201, the resistance change layer 220 on the base insulating layer 210, a channel layer 230 on the resistance change layer 220, a gate dielectric layer 240 on the channel layer 230, and a gate electrode layer 250 on the gate dielectric layer 240. In addition, the semiconductor device 2 may include the source electrode layer 260 and the drain electrode layer 270 disposed to contact opposite ends of the channel layer 230, respectively.

The configurations of the substrate 201, the base insulating layer 210, the channel layer 230, the gate dielectric layer 240, and the gate electrode layer 250 may be substantially the same as those of the substrate 101, the base insulating layer 110, the channel layer 130, the gate dielectric layer 140, and the gate electrode layer 150 of the semiconductor device 1 of FIG. 1A.

Referring to FIG. 5, the source electrode layer 260, the channel layer 230, and the drain electrode layer 270 may be disposed on the resistance change layer 220. However, in semiconductor device 2, a lower surface 260B of the source electrode layer 260 and a lower surface 270B of the drain electrode layer 270 may be disposed on a plane different from a lower surface 230B of the channel layer 230. The source electrode layer 260 may be disposed in a space recessed by a first thickness t1 from an interface between the channel layer 230 and the resistance change layer 220 in an inward direction (i.e., in a direction parallel to the z-direction). Likewise, the drain electrode layer 270 may be disposed in a space recessed by a second thickness t2 from an interface between the channel layer 230 and the resistance change layer 220 in an inward direction (i.e., in a direction parallel to the z-direction). Accordingly, a side surface 260W of the source electrode layer 260 may contact the gate dielectric layer 240, the channel layer 230, and the resistance change layer 220. In addition, a side surface 270W of the drain electrode layer 270 may contact the gate dielectric layer 240, the channel layer 230, and the resistance change layer 220.

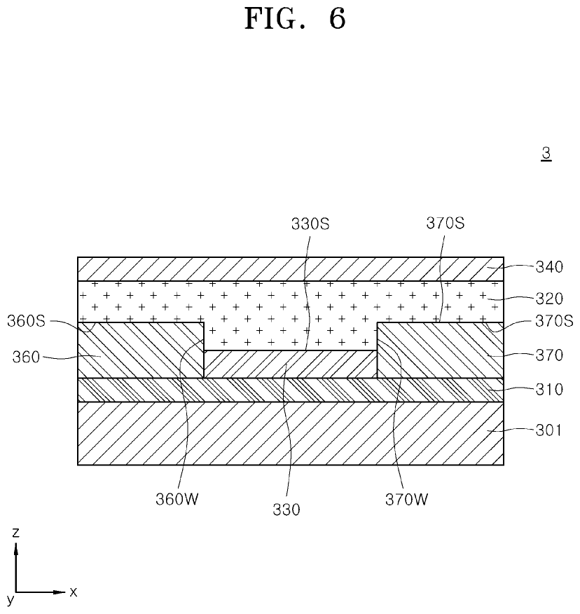

FIG. 6 is a cross-sectional view schematically illustrating a semiconductor device according to yet another embodiment of the present disclosure. Referring to FIG. 6, a semiconductor device 3 may include a conductive gate substrate 301, a gate dielectric layer 310, a channel layer 330, a resistance change layer 320, a source electrode layer 360, and a drain electrode layer 370. In addition, the semiconductor device 3 may include a passivation layer 340 covering the resistance change layer 320 over the conductive gate substrate 301.

Referring to FIG. 6, the conductive gate substrate 301 may include a semiconductor material. Specifically, semiconductor material may include silicon (Si), germanium (Ge), gallium arsenide (GaAs), molybdenum selenide (MoSe₂), hafnium selenide (HfSe₂), indium selenide (InSe), gallium selenide (GaSe), black phosphorus, indium-gallium-zinc oxide (IGZO), or a combination of two or more thereof. The conductive gate substrate 301 may have conductivity by including a dopant injected into the semiconductor material. As an example, the conductive gate substrate 301 may be doped with an N-type or P-type dopant. The conductive gate substrate 301 may serve as a gate electrode to which a gate voltage is applied from the outside.

The gate dielectric layer 310 may be disposed on the conductive gate substrate 301. The gate dielectric layer 310 may be disposed to contact the conductive gate substrate 301. The material of the gate dielectric layer 310 may be substantially the same as the material of the gate dielectric layer 140 of the semiconductor device 1 of FIG. 1A.

The source electrode layer 360, the channel layer 330, and the drain electrode layer 370 may be disposed on the gate dielectric layer 310. The source electrode layer 360 and the drain electrode layer 370 may respectively contact different ends of the channel layer 330.

Referring to FIG. 6, an upper surface 360S of the source electrode layer 360 and an upper surface 370S of the drain electrode layer 370 may be disposed at a level higher than an upper surface 330S of the channel layer 330. Accordingly, the side surface 360W of the source electrode layer 360 may contact the resistance change layer 320 and the channel layer 330. In addition, the side surface 370W of the drain electrode layer 370 may contact the resistance change layer 320 and the channel layer 330.

In other embodiments that differ from those illustrated by FIG. 6, the upper surface 360S of the source electrode layer 360, the upper surface 330S of the channel layer 330, and the upper surface 370S of the drain electrode layer 370 may be disposed at the same level. The side surface 360W of the source electrode layer 360 and the side surface 370W of the drain electrode layer 370 may contact only the channel layer 330.

Referring again to FIG. 6, the resistance change layer 320 may be disposed on the source electrode layer 360, the drain electrode layer 370, and the channel layer 330. The resistance change layer 320 may include a plurality of carbon nanostructures. The material of the resistance change layer 320 may be substantially the same as the material of the resistance change layer 120 of the semiconductor device of FIG. 1A.

The passivation layer 340 may be disposed on the resistance change layer 320. The passivation layer 340 may physically and chemically protect the resistance change layer 320 from an external environment. The passivation layer 340 may include, as an example, oxide, nitride, oxynitride, or a combination thereof.

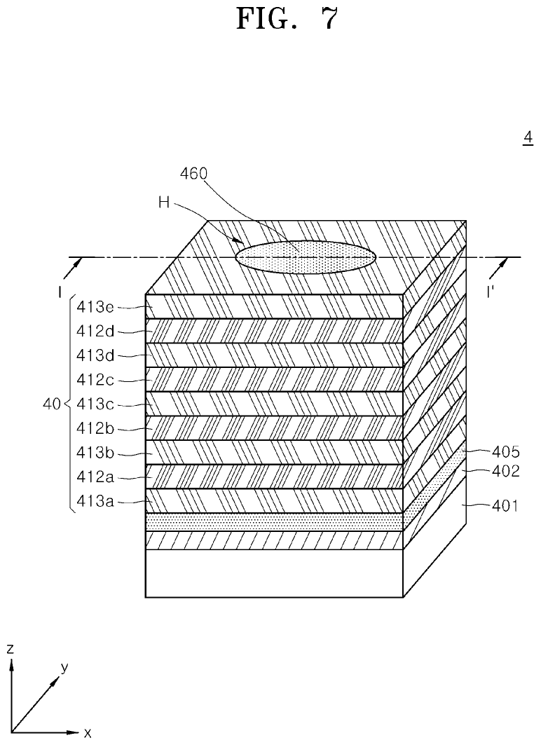

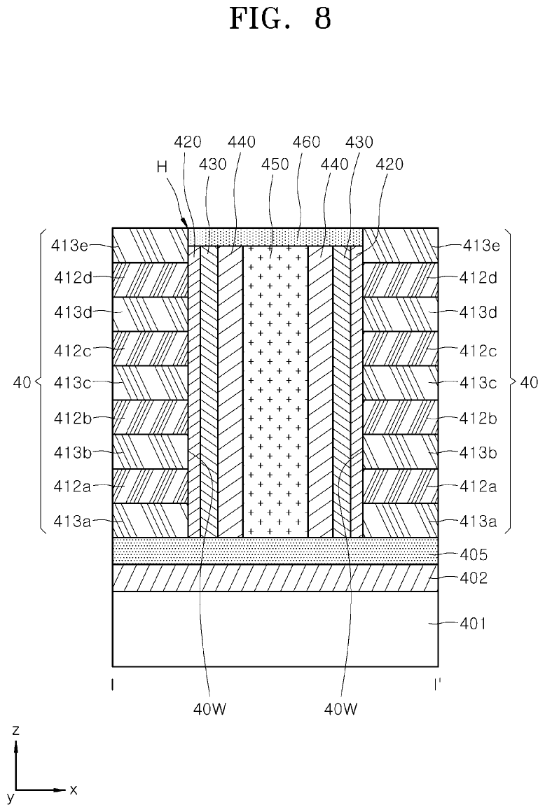

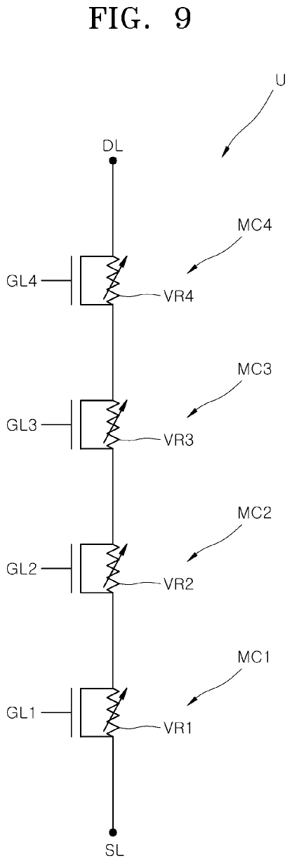

FIG. 7 is a perspective view schematically illustrating a semiconductor device according to yet another embodiment of the present disclosure. FIG. 8 is a cross-sectional view taken along line I-I′ of the semiconductor device of FIG. 7. FIG. 9 is a circuit diagram of a semiconductor device according to an embodiment of the present disclosure. The circuit diagram of FIG. 9 may correspond to a portion of the semiconductor device of FIGS. 7 and 8.

Referring to FIGS. 7 and 8, a semiconductor device 4 may include a substrate 401 and a gate structure 40 disposed over the substrate 401. In addition, the semiconductor device 4 may include a hole pattern H penetrating the gate structure 40 over the substrate 401. The semiconductor device 4 may include a gate dielectric layer 420 disposed along a sidewall surface 40W of the gate structure 40 within the hole pattern H, a channel layer 430 disposed on a sidewall surface of the gate dielectric layer 420, and a resistance change layer 440 disposed on a sidewall surface of the channel layer 430.

The semiconductor device 4 may further include a channel lower contact layer 405 contacting one end of the channel layer 430 over the substrate 401. The semiconductor device 4 may further include a channel upper contact layer 460 contacting the other end of the channel layer 430. The channel upper contact layer 460 may be disposed to be spaced apart from the channel lower contact layer 405 in a direction (i.e., z-direction) perpendicular to an upper or lower surface of the substrate 401.

Referring to FIGS. 7 and 8, the substrate 401 may include a semiconductor material. Specifically, the semiconductor material may include silicon (Si), germanium (Ge), gallium arsenide (GaAs), molybdenum selenide (MoSe₂), hafnium selenide (HfSe₂), indium selenide (InSe), gallium selenide (GaSe), black phosphorus, indium-gallium-zinc oxide (IGZO), or a combination of two or more thereof.

A base insulating layer 402 may be disposed on the substrate 401. The base insulating layer 402 may electrically insulate the channel lower contact layer 405 from the substrate 401. The base insulating layer 402 may include an insulating material. The insulating material may include, as an example, oxide, nitride, oxynitride, or a combination of two or more thereof.

Although not illustrated in FIG. 7, the substrate 401 may include an integrated circuit. As an example, the integrated circuit may constitute an active element such as a diode or a transistor. At least one conductive layer and at least one insulating layer may be disposed between the substrate 401 and the base insulating layer 402. The conductive layer and the insulating layer may constitute a passive element such as a capacitor and a resistor.

The channel lower contact layer 405 may be disposed on the base insulating layer 402. The channel lower contact layer 405 may be electrically connected to the channel layer 430. Although not illustrated, the channel lower contact layer 405 may be electrically connected to a source line. The channel lower contact layer 405 may include a conductive material. The conductive material may include, as an example, doped semiconductor, metal, conductive metal nitride, conductive metal carbide, conductive metal silicide, or conductive metal oxide. The conductive material may include, as an example, silicon (Si) doped with an n-type or p-type dopant, tungsten (W), titanium (Ti), copper (Cu), aluminum (Al), ruthenium (Ru), platinum (Pt), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

The gate structure 40 may be disposed on the channel lower contact layer 405. The gate structure 40 may include first to fourth gate electrode layers 412a, 412b, 412c, and 412d and first to fifth interlayer insulating layers 413a, 413b, 413c, 413d, and 413e, which are alternately stacked along a first direction (i.e., z-direction) perpendicular to an upper or lower surface of the substrate 401. The first interlayer insulating layer 413a may be disposed to contact the channel lower contact layer 405. The fifth interlayer insulating layer 413e may be disposed as the uppermost layer of the gate structure 40.

Each of the first to fourth gate electrode layers 412a, 412b, 412c, and 412d may include a conductive material. The conductive material may include, as an example, doped semiconductor, metal, conductive metal nitride, conductive metal carbide, conductive metal silicide, or conductive metal oxide. The conductive material may include, as an example, silicon (Si) doped with an n-type or p-type dopant, tungsten (W), titanium (Ti), copper (Cu), aluminum (Al), ruthenium (Ru), platinum (Pt), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof. Each of the first to fifth interlayer insulating layers 413a, 413b, 413c, 413d, and 413e may include an insulating material. The insulating material may include, as an example, oxide, nitride, oxynitride, or a combination of two or more thereof.

In some embodiments, the number of gate electrode layers of the gate structure 40 might not be limited to four. The gate electrode layers may be arranged in different numbers, and the interlayer insulating layers may insulate the various numbers of gate electrode layers from each other along the first direction (i.e., z-direction).

Referring to FIGS. 7 and 8, the hole pattern H penetrating the gate structure 40 may be formed on the channel lower contact layer 405. In an embodiment, the hole pattern H may be formed by a known lithography process and an etching process. The hole pattern H may expose the sidewall surface 40W of the gate structure 40.

The gate dielectric layer 420 may be disposed inside the hole pattern H to cover the sidewall surface 40W of the gate structure 40. The gate dielectric layer 420 may include, as an example, oxide, nitride, oxynitride, or a combination of two or more thereof. Specifically, the gate dielectric layer 420 may include silicon oxide, silicon nitride, silicon oxynitride, aluminum oxide, hafnium oxide, zirconium oxide, or a combination of two or more thereof.

The channel layer 430 may be disposed on the sidewall surface of the gate dielectric layer 420. The channel layer 430 may include a semiconductor material. The semiconductor material may include, as an example, silicon (Si), germanium (Ge), gallium arsenide (GaAs), or the like. As another example, the semiconductor material may include a 2D semiconductor material. The 2D semiconductor material may include transition metal dichalcogenide (TMDC), black phosphorus, or the like. The transition metal dichalcogenide may include, as an example, molybdenum selenide (MoSe₂), hafnium selenide (HfSe₂), indium selenide (InSe), gallium selenide (GaSe), or the like. The semiconductor material may include, as an example, metal oxide such as indium-gallium-zinc oxide (IGZO). The channel layer 430 may be doped with a dopant to have conductivity. The conductivity of the channel layer 430 may be proportional to the amount of the dopant.

Referring to FIG. 8, the resistance change layer 440 may be disposed on the sidewall surface of the channel layer 430. The resistance change layer 440 may be disposed to contact the channel layer 430. The resistance change layer 440 may include a plurality of carbon nanostructures. In an embodiment, the resistance change layer 440 may be an integrated body of a plurality of carbon nanostructures. The plurality of carbon nanostructures may have electrical conductivity. The plurality of carbon nanostructures may include, as an example, carbon nanotubes or carbon nanorods.

The electrical resistance of the resistance change layer 440 may vary according to the distribution state of the plurality of carbon nanostructures, as described with reference to FIGS. 2A and 2B. As an example, as the plurality of carbon nanostructures are distributed in the resistance change layer 440 and form additional contact points, the electrical resistance of the resistance change layer 440 may decrease.

The electrical resistance of the resistance change layer 440 may be lower than the electrical resistance of the channel layer 430 regardless of the distribution state of the plurality of carbon nanostructures. However, as will be described later, when a conductive channel is formed in the channel layer 430, the electrical resistance of the conductive channel may be lower than that of the resistance change layer 440.

A filling insulating layer 450 may be disposed inside the hole pattern H. The filling insulating layer 450 may be disposed to contact the resistance change layer 440. The filling insulating layer 450 may include, as an example, oxide, nitride, oxynitride, or a combination of two or more thereof.

The channel upper contact layer 460 may be disposed on the filling insulating layer 450 and in the hole pattern H. The channel upper contact layer 460 may contact one end of each of the gate dielectric layer 420, the channel layer 430, and the resistance change layer 440. Although not illustrated, the channel upper contact layer 460 may be electrically connected to a bit line. In some embodiments not illustrated in FIG. 8, the channel upper contact layer 460 may be disposed outside the hole pattern H. In such cases, the channel upper contact layer 460 may be electrically connected to at least the channel layer 430.

The channel upper contact layer 460 may include a conductive material. The channel upper contact layer 460 may be made of substantially the same material as the channel lower contact layer 405.

As described above, according to an embodiment of the present disclosure, the semiconductor device 4 may include a gate structure 40 disposed on the channel lower contact layer 405. In addition, the semiconductor device 4 may include a gate dielectric layer 420, a channel layer 430, and a resistance change layer 440 sequentially disposed from the sidewall surface 40W of the gate structure 40.

In some embodiments that differ from that illustrated in FIG. 8, positions of the channel layer 430 and the resistance change layer 440 on the sidewall surface 40W of the gate structure 40 may be changed. That is, the gate dielectric layer 420 may be disposed on the sidewall surface 40W of the gate structure 40, the resistance change layer 440 may be disposed on the gate dielectric layer 420, and the channel layer 430 may be disposed on the resistance change layer 440.

Referring to the circuit diagram U of FIG. 9, a semiconductor device may include first to fourth memory cells MC1, MC2, MC3, and MC4 in the form of transistors. The first to fourth memory cells MC1, MC2, MC3, and MC4 may be connected in series to each other in the form of a string between a source electrode SL and a drain electrode DL. The first to fourth memory cells MC1, MC2, MC3, and MC4 may include first to fourth variable resistance elements VR1, VR2, VR3, and VR4, respectively, disposed in channels of the transistors. The first to fourth variable resistance elements VR1, VR2, VR3, and VR4 may function as nonvolatile memory elements of the first to fourth memory cells MC1, MC2, MC3, and MC4, respectively.

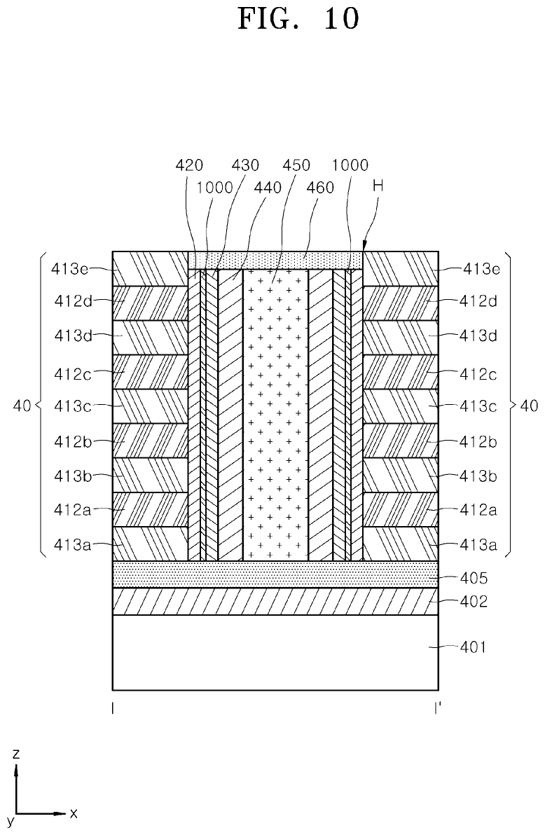

Referring to FIGS. 7 to 9 together, the source electrode SL and the drain electrode DL of FIG. 9 may correspond to a source electrode (not illustrated) and a drain electrode (not illustrated) electrically connected to the channel lower contact layer 405 and the channel upper contact layer 460 in FIGS. 7 and 8, respectively. First to fourth gate electrodes GL1, GL2, GL3, and GL4 of FIG. 9 may correspond to the first to fourth gate electrode layers 412a, 412b, 412c, and 412d of FIGS. 7 and 8, respectively. The first to fourth variable resistance elements VR1, VR2, VR3, and VR4 of FIG. 9 may correspond to regions of the resistance change layer 440 controlled by the first to fourth gate electrode layers 412a, 412b, 412c, and 412d in FIGS. 7 and 8, respectively. The configuration of the regions of the resistance change layer 440 controlled by the first to fourth gate electrode layers 412a, 412b, 412c, and 412d will be described in detail through the operation method of the semiconductor device related to FIGS. 10 to 12 below.

FIGS. 10 to 12 are diagrams schematically illustrating an operation method of a semiconductor device according to an embodiment of the present disclosure. The operation method of the semiconductor device described with reference to FIGS. 10 to 12 may be applied to the operation method of a semiconductor device 4 described above with reference to FIGS. 7 and 8. The operation method of the semiconductor device may include a write operation and a read operation for a target memory cell. For convenience of description, as an example, the write operation and the read operation are described using a memory cell including a third gate electrode layer 412c and a portion of the resistance change layer 440 controlled by the third gate electrode layer 412c of the semiconductor device 4 in FIGS. 7 and 8. The memory cell may correspond to the third memory cell MC3, which includes the third variable resistance element VR3 in the circuit diagram of FIG. 9.

Referring to FIG. 10, for the write operation, a first gate voltage including a bias having a positive polarity is applied to the first to fourth gate electrode layers 412a, 412b, 412c, and 412d while the channel layer 430 is grounded. An electric field generated by the first gate voltage may form a conductive channel 1000 in a region of the channel layer 430 in contact with the gate dielectric layer 420. The conductive channel 1000 may be formed in a continuous shape in the channel layer 430 along the z-direction.

The conductive channel 1000 may be formed in the continuous shape along the z-direction by the following mechanism. The electric field generated by the first gate voltage may act not only on the region of the channel layer 430 directly overlapping with the first to fourth gate electrode layers 412a, 412b, 412c, and 412d along the x-direction, but also on the region of the channel layer 430 that does not directly overlap with the first to fourth gate electrode layers 412a, 412b, 412c, and 412d in the x-direction, as a fringing electric field. That is, in the channel layer region 430 that does not directly overlap with the first to fourth gate electrode layers 412a, 412b, 412c, and 412d in the x-direction, an electric field formed by another gate electrode layer adjacent in the z-direction may expand in the z-direction, so that the conductive channel 1000 may be formed in the region of the corresponding channel layer 430. Accordingly, the conductive channel 1000 may be formed to be continuous along the z-direction.

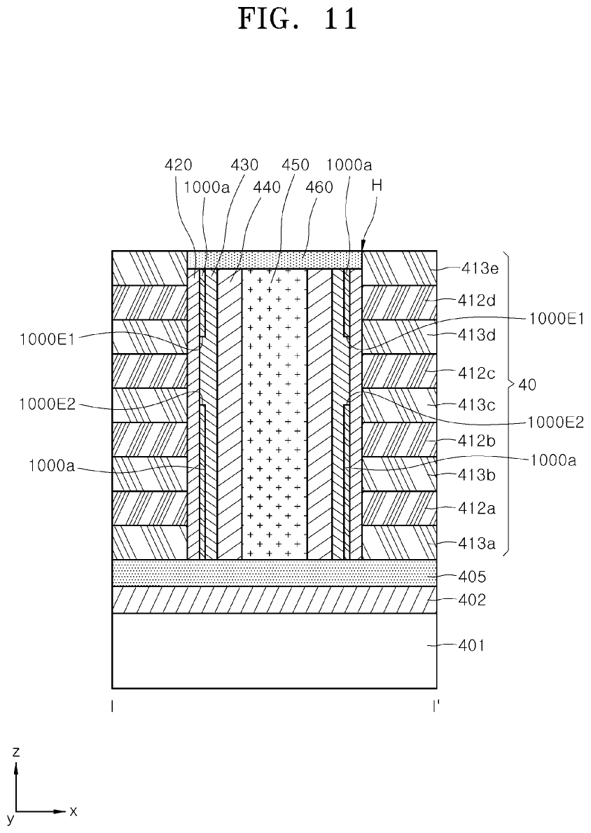

Referring to FIG. 11, the first gate voltage applied to the first gate electrode layer 412a, the second gate electrode layer 412b, and the fourth gate electrode layer 412d is maintained, and the first gate voltage applied to the third gate electrode layer 412c is subsequently removed. Accordingly, a portion of the conductive channel 1000 electrically controlled by the third gate electrode layer 412c may be disconnected along the z-direction, and the conductive channel 1000 may be converted into a disconnected conductive channel 1000a and may be electrically insulated between both ends 1000E1 and 1000E2.

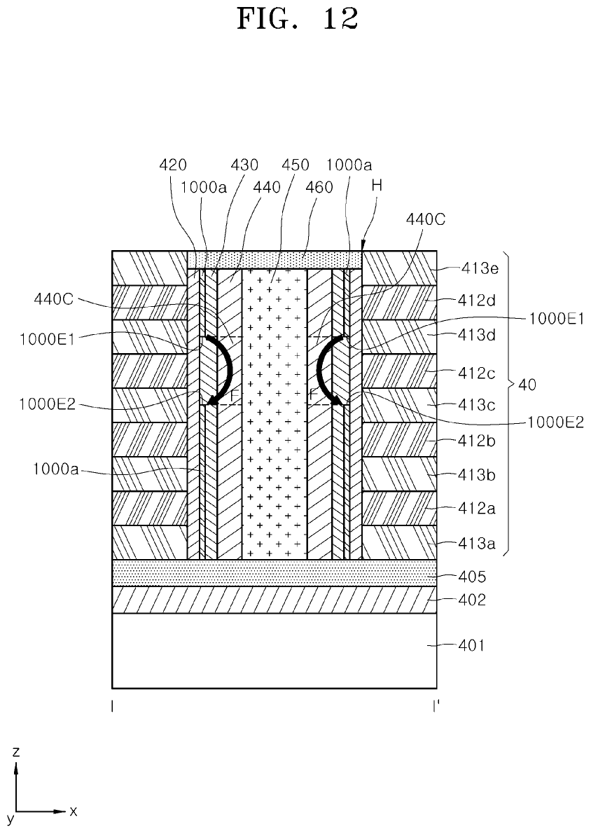

Referring to FIG. 12, in a state in which the first gate voltage is applied to the first gate electrode layer 412a, the second gate electrode layer 412b, and the fourth gate electrode layer 412d, and the first gate voltage is removed from the third gate electrode layer 412c, a write voltage may be applied between the channel lower contact layer 405 and the channel upper contact layer 460. Accordingly, the write operation for the third memory cell MC3 may be performed. In this case, the write voltage may be concentrated between both ends 1000E1 and 1000E2 of the disconnected conductive channel 1000a.

Subsequently, a write electric field F formed by the write voltage may be applied to a portion 440C of the resistance change layer 440 positioned between the ends 1000E1 and 1000E2 of the disconnected conductive channel 1000a. The distribution state of the plurality of carbon nanostructures inside the resistance change layer 440 may be changed by the write electric field F. The plurality of carbon nanostructures may have a distribution state having various contact points according to the polarity and magnitude of the write voltage. Depending on the distribution state of the plurality of carbon nanostructures, the portion 440C of the resistance change layer 440 corresponding to the third memory cell MC3 may have various electrical resistance states. The write operation for the third memory cell MC3 may be performed through the above-described method.

Referring again to FIG. 12, the electrical resistance state stored in the third memory cell MC3 may be read through the following read operation. In a state in which the first gate voltage is applied to the first gate electrode layer 412a, the second gate electrode layer 412b, and the fourth gate electrode layer 412d, and the first gate voltage is removed from the third gate electrode layer 412c, a read voltage may be applied between the channel lower contact layer 405 and the channel upper contact layer 460. In this case, the read voltage may be concentrated between both ends 1000E1 and 1000E2 of the disconnected conductive channel 1000a.

Subsequently, the electric field formed by the read voltage may be applied to the portion 440C of the resistance change layer 440 positioned between both ends 1000E1 and 1000E2 of the disconnected conductive channel 1000a. The electric field resulting from the read voltage may not change the distribution state of the plurality of carbon nanostructures inside the portion 440C of the resistance change layer 440. By reading the current flowing through the portion 440C of the resistance change layer 440, the electrical resistance of the portion 440C of the resistance change layer 440 of the third memory cell MC3 may be read.

Through the above described methods, a write operation and a read operation for a third memory cell MC3 of a semiconductor device 4 may be performed. Write operations and read operations for other memory cells MC1, MC2, and MC4 of the semiconductor device 4 may be performed in substantially the same manner.

Embodiments of the present disclosure have been disclosed for illustrative purposes. Those skilled in the art will appreciate that various modifications, additions and substitutions are possible, without departing from the scope and spirit of the present disclosure and the accompanying claims.

What is claimed is:

1. A semiconductor device comprising:
a substrate;
a resistance change layer disposed on the substrate and including a plurality of carbon nanostructures;
a channel layer disposed on the resistance change layer;
a gate electrode layer disposed on the channel layer; and
a source electrode layer and a drain electrode layer disposed to contact portions of the channel layer.

2. The semiconductor device of claim 1, wherein the plurality of carbon nanostructures comprises carbon nanotubes or carbon nanorods.

3. The semiconductor device of claim 1, wherein each of the plurality of carbon nanostructures has a length of 1 nm to 100 nm.

4. The semiconductor device of claim 1, wherein the resistance change layer has a different electrical resistance corresponding to different distribution states of the plurality of carbon nanostructures.

5. The semiconductor device of claim 1, wherein the channel layer comprises a semiconductor material.

6. The semiconductor device of claim 5, wherein the semiconductor material includes at least one selected from the group consisting of silicon (Si), germanium (Ge), gallium arsenide (GaAs), molybdenum selenide (MoSe₂), hafnium selenide (HfSe₂), indium selenide (InSe), gallium selenide (GaSe), black phosphorus, and indium-gallium-zinc oxide (IGZO).

7. The semiconductor device of claim 1, further comprising a gate dielectric layer disposed between the channel layer and the gate electrode layer.

8. The semiconductor device of claim 1, wherein the source electrode layer, the channel layer, and the drain electrode layer are disposed on the resistance change layer, and
wherein a lower surface of the source electrode layer and a lower surface of the drain electrode layer are disposed on a plane different from a plane formed by a lower surface of the channel layer.

9. The semiconductor device of claim 1, wherein the source electrode layer and the drain electrode layer are disposed to contact opposite ends of the channel layer, and
wherein each of the source electrode layer and the drain electrode layer is disposed to contact the resistance change layer.

10. A semiconductor device comprising:
a conductive gate substrate;
a gate dielectric layer disposed on the conductive gate substrate;
a channel layer disposed on the gate dielectric layer and including a semiconductor material;
a source electrode layer and a drain electrode layer disposed on the gate dielectric layer to contact opposite ends of the channel layer; and
a resistance change layer disposed over the conductive gate substrate to contact the source electrode layer, the drain electrode layer, and the channel layer,
wherein the resistance change layer comprises a plurality of carbon nanostructures.

11. The semiconductor device of claim 10, wherein the plurality of carbon nanostructures comprises carbon nanotubes or carbon nanorods.

12. The semiconductor device of claim 10, wherein the resistance change layer has a different electrical resistance according to distribution states of the plurality of carbon nanostructures.

13. A semiconductor device comprising:
a substrate;
a gate structure disposed over the substrate, the gate structure including at least one gate electrode layer and at least one interlayer insulating layer that are alternately stacked;
a channel layer, including a semiconductor material, that is disposed over the substrate and along a sidewall surface of the gate structure; and
a resistance change layer disposed over the substrate to contact the channel layer and including a plurality of carbon nanostructures.

14. The semiconductor device of claim 13, further comprising a gate dielectric layer disposed between the sidewall surface of the gate structure and the channel layer.

15. The semiconductor device of claim 14, wherein the gate dielectric layer is disposed on the sidewall surface of the gate structure, the channel layer is disposed on the gate dielectric layer, and the resistance change layer is disposed on the channel layer.

16. The semiconductor device of claim 14, wherein the gate dielectric layer is disposed on the sidewall surface of the gate structure, the resistance change layer is disposed on the gate dielectric layer, and the channel layer is disposed on the resistance change layer.

17. The semiconductor device of claim 13, wherein the plurality of carbon nanostructures comprises carbon nanotubes or carbon nanorods.

18. The semiconductor device of claim 13, wherein the resistance change layer is configured to have different electrical resistances according to distribution states of the plurality of carbon nanostructures.

19. The semiconductor device of claim 13, further comprising:
a source electrode layer in contact with one end of the channel layer over the substrate; and
a drain electrode layer in contact with the other end of the channel layer and located opposite to the one end of the channel layer.

20. The semiconductor device of claim 19, wherein the source electrode layer and the drain electrode layer are disposed to contact portions of the resistance change layer.
